(19) United States
(12) Patent Application Publication
(10) Pub. No.: US 2017/0347483 A1
(43) Pub. Date: Nov. 30, 2017

(54) ELECTRICAL DEVICE

(71) Applicant: ABB Technology Oy, Helsinki (FI)

(72) Inventors: Pertti Seväkivi, Lepsama (FI); Niko Björkman, Klaukkala (FI)

(21) Appl. No.: 15/604,714

(22) Filed: May 25, 2017

(30) Foreign Application Priority Data
May 26, 2016 (EP) 16171475.3

(51) Int. Cl. H05K 7/18; H05K 5/00; H02M 7/00

(52) U.S. Cl. CPC H05K 7/18; H02M 7/003; H05K 5/0017

(57) ABSTRACT

An electrical device comprising a frame, a first wall connected to the frame, a power converter adapted to convert electric energy from one form to another, the power converter comprising at least one power converter element, and a controller adapted to control the power converter, the controller comprising at least one controller element. The first wall is pivotally connected to the frame about a first pivoting axis such that the first wall is adapted to pivot between a first position in which the first wall is adapted to protect the at least one controller element, and a second position which is adapted to provide an access to the at least one controller element for maintenance and repair.

### FIELD OF THE INVENTION

The invention relates to an electrical device comprising a power converter and a controller element for controlling the power converter.

In a known power converter assembly a location of a controller element adapted to control a power converter of the assembly is simply determined based on connections between different components selected on the grounds of their electrotechnical properties. In the known power converter assembly, the controller element of the power converter is located deep inside the power converter assembly thereby making maintenance work relating to the controller element difficult and time-consuming.

### BRIEF DESCRIPTION OF THE INVENTION

An object of the present invention is to provide an electrical device so as to alleviate the above disadvantage. The objects of the invention are achieved by an electrical device which is characterized by what is stated in the independent claim. The preferred embodiments of the invention are disclosed in the dependent claims.

The invention is based on the idea of providing an electrical device with a wall which is pivotally connected to the frame of the electrical device, the wall being adapted to pivot between a first position in which the wall is adapted to protect the controller element, and a second position which provides an access to the controller element for maintenance and repair. In an embodiment the controller element is attached to an inner surface of the pivoting wall.

An advantage of the electrical device of the invention is that the controller element is easily accessible simply by turning the wall into an open position.

### BRIEF DESCRIPTION OF THE DRAWINGS

In the following the invention will be described in greater detail by means of preferred embodiments with reference to the attached drawings, in which

FIG. 1 shows an electrical device assembly comprising an electrical device according to an embodiment of the invention;

FIG. 2 shows the electrical device assembly of FIG. 1 with a front wall of the electrical device in an open position;

FIG. 3A shows the electrical device of FIG. 1 in a partially disassembled state;

FIG. 3B shows the partially disassembled electrical device of FIG. 3A from a different direction; and

FIGS. 4A and 4B illustrate assembling of the electrical device of FIG. 3A.

### DETAILED DESCRIPTION OF THE INVENTION

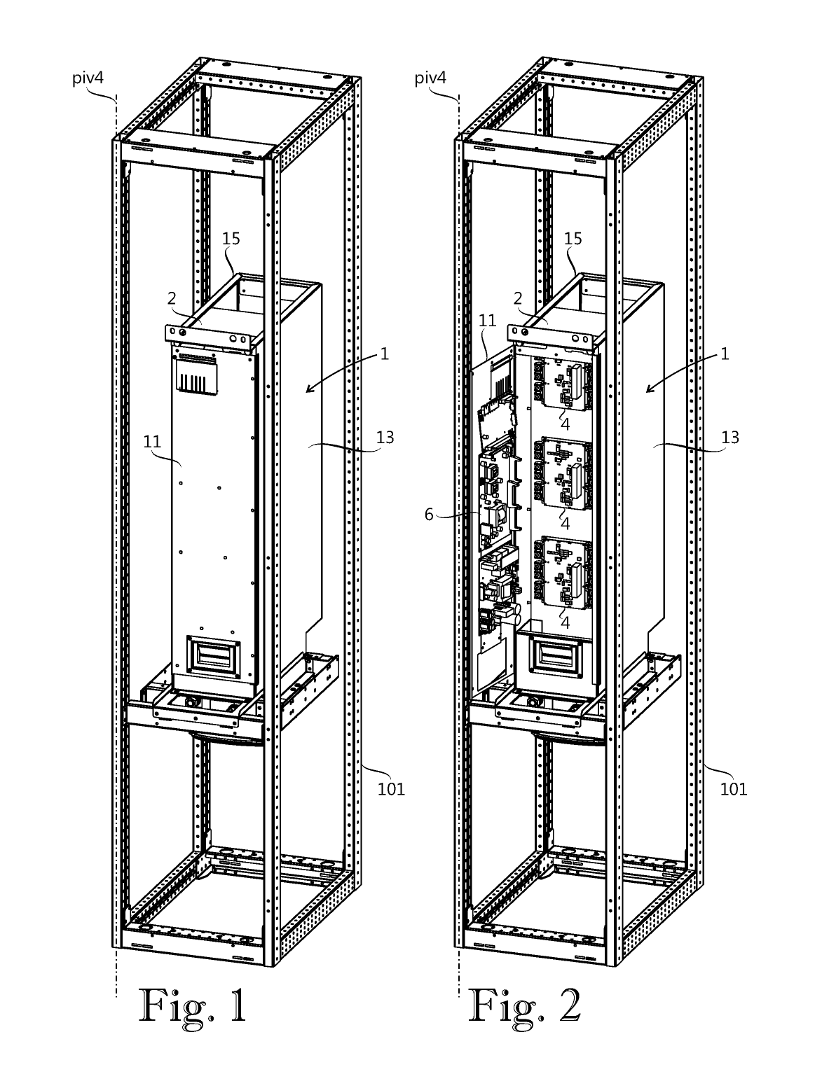

FIG. 1 shows an electrical device assembly comprising a rack 101 of an electric cabinet, and an electrical device 1 mounted in the rack 101. In a use situation the electric cabinet comprises side walls and an openable door mounted on the rack 101. The electric cabinet defines a mounting space that accommodates the electrical device 1. The openable door is adapted to provide access into the mounting space in an open position of the openable door. The side walls and the openable door have been omitted from FIG. 1 in order to provide a better view of the electrical device 1.

The electrical device 1 comprises a frame 2, a first wall 11 connected to the frame 2, a power converter adapted to convert electric energy from one form to another, and a controller adapted to control the power converter. The controller is communicatively and electrically connected to components mounted on the frame 2. The first wall 11 is pivotally connected to the frame 2 about a first pivoting axis such that the first wall 11 is adapted to pivot between a first position shown in FIG. 1, and a second position shown in FIG. 2. There is a hinge between the first wall 11 and the frame 2, the hinge providing the pivotal connection between the first wall 11 and the frame 2.

The controller comprises a controller element 6. In the first position the first wall 11 is adapted to protect the controller element 6. The second position of the first wall 11 provides an access to the controller element 6 for maintenance and repair. The first position of the first wall 11 can be considered as a closed position, and the second position of the first wall 11 can be considered as an open position.

The controller element 6 is attached to the first wall 11, on an inner surface of the first wall 11. The controller element 6 is adapted to pivot with the first wall 11. The controller element 6 comprises a circuit board defining a circuit board plane which is parallel to a first wall plane defined by the first wall 11.

The inner surface of the first wall 11 is a surface of the first wall 11 which faces towards inside of the electrical device 1 when the first wall 11 is in the first position. An outer surface of the first wall 11 is a surface of the first wall 11 which faces towards outside of the electrical device 1 when the first wall 11 is in the first position. The outer surface of the first wall 11 can be seen in FIG. 1.

The power converter comprises three power converter elements 4. The power converter elements 4 are attached to the frame 2. Each of the power converter elements 4 comprises a plurality of controllable semiconductor switches adapted for the power conversion function of the power converter. The controller is adapted to control the controllable semiconductor switches selectively into conducting state and non-conducting state in order to convert electric energy from one form to another. The power converter elements 4 define a power converter element plane which is parallel to the first wall plane when the first wall 11 is in the first position thereof. Distance between the power converter element plane and the circuit board plane is small when the first wall 11 is in the first position thereof.

FIG. 2 shows that the second position of the first wall 11 provides an access to the power converter elements 4 for maintenance and repair. In the second position of the first wall 11 the first wall plane is in an angle relative to the power converter element plane, the angle being over 90° . When the first wall 11 is in the second position, inspecting and replacing the power converter elements 4 is easy.

In an alternative embodiment a controller element is located in a corresponding position as the power converter elements 4 in FIG. 2. In the alternative embodiment the controller element is attached to a frame of an electrical device, and a first wall is pivotally connected to the frame about a first pivoting axis such that the first wall is adapted to pivot between a first position and a second position. In the first position the first wall is adapted to protect the controller element by covering the controller element. In the second position the first wall does not cover the controller element, and provides an access to the controller element for maintenance and repair.

The power converter of the electrical device 1 comprises a frequency converter. In an alternative embodiment a power converter comprises an inverter, a rectifier, a DC-to-DC converter, or some other type of power converter adapted to convert electric energy from one form to another.

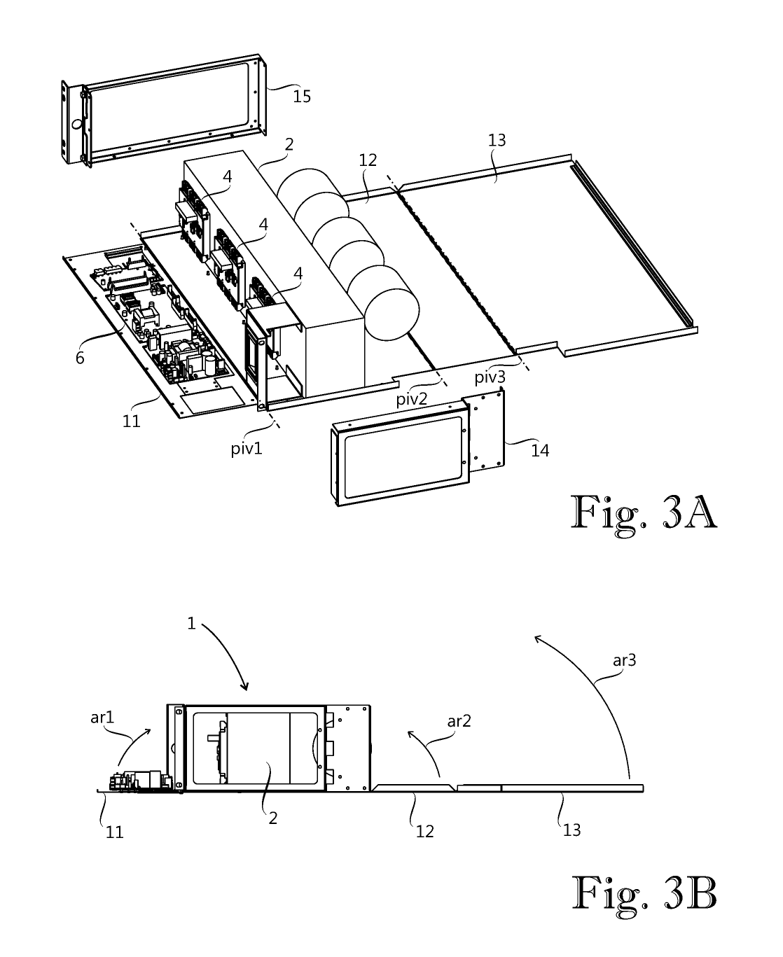

FIG. 3A shows the electrical device 1 of FIG. 1 in a partially disassembled state. In FIG. 3A the first pivoting axis about which the first wall 11 is pivotally connected to the frame 2 is denoted with reference sign piv1. The electrical device 1 comprises a second wall 12 pivotally connected to the frame 2 about a second pivoting axis piv2, such that the second wall 12 is adapted to pivot between a first position and a second position relative to the frame 2. There is a hinge between the second wall 12 and the frame 2, the hinge providing the pivotal connection between the second wall 12 and the frame 2. The second pivoting axis piv2 is substantially parallel to the first pivoting axis piv1.

The electrical device 1 comprises a third wall 13 pivotally connected to the second wall 12 about a third pivoting axis piv3. There is a hinge between the third wall 13 and the second wall 12, the hinge providing the pivotal connection between the third wall 13 and the second wall 12. The third wall 13 is adapted to pivot between a first position and a second position relative to the second wall 12. The second pivoting axis piv2 is substantially parallel to the third pivoting axis piv3.

The first wall 11 defines a first wall plane, the second wall 12 defines a second wall plane, and the third wall 13 defines a third wall plane. In FIG. 3A the first wall 11 and the second wall 12 are in their second positions relative to the frame 2, and the third wall 13 is in the second position relative to the second wall 12, wherein the first wall plane, the second wall plane and the third wall plane are coplanar planes. FIG. 3A shows that the position where the first wall 11, the second wall 12 and the third wall 13 are located on a same plane provides good access to components of the electrical device 1. When the first wall 11, the second wall 12 and the third wall 13 are located on a same plane, installing components into the frame 2 is easy.

The electrical device 1 comprises a fourth wall 14 and a fifth wall 15 which are connected to the frame 2 in the assembled state of the electrical device 1 shown in FIG. 1. In FIG. 3A the fourth wall 14 and the fifth wall 15 are detached from the frame 2. FIG. 3A shows that the fourth wall 14 and the fifth wall 15 are substantially open walls which can be considered as rectangular framing elements.

In the assembled state of the electrical device 1 the fourth wall 14 and the fifth wall 15 define end walls of the electrical device. The fourth wall 14 defines a fourth wall plane and the fifth wall 15 defines a fifth wall plane. The fourth wall plane and the fifth wall plane are parallel to each other and located at a distance from each other. The electrical device 1 is adapted such that when the first wall 11 and the second wall 12 are in their first positions relative to the frame 2, and the third wall 13 is in the first position relative to the second wall 12, the fourth wall plane and the fifth wall plane extend perpendicular to the first wall plane, the second wall plane and the third wall plane. The controller and the power converter are located inside a space defined by the first wall 11, the second wall 12, the third wall 13, the fourth wall 14 and the fifth wall 15.

It should be noted that in the assembled state of the electrical device 1 it is not possible to turn the second wall 12 about the second pivoting axis piv2, or the third wall 13 about the third pivoting axis piv3 because the third wall 13 is connected by screws (not depicted) to the fourth wall 14 and the fifth wall 15. However, if said screw connections were opened, it would again be possible to pivot the second wall 12 and the third wall 13 about their respective pivoting axes. Herein a pivotal connection between two components means that there is a hinge between the two components. It is not required that pivoting the two components relative to each other is possible during any situation.

FIG. 3B shows the partially disassembled electrical device of FIG. 3A from a direction perpendicular to the fourth wall plane. Arrows ar1, ar2 and ar3 illustrate directions in which the first wall 11, the second wall 12 and the third wall 13 are turned during assembly of the electrical device.

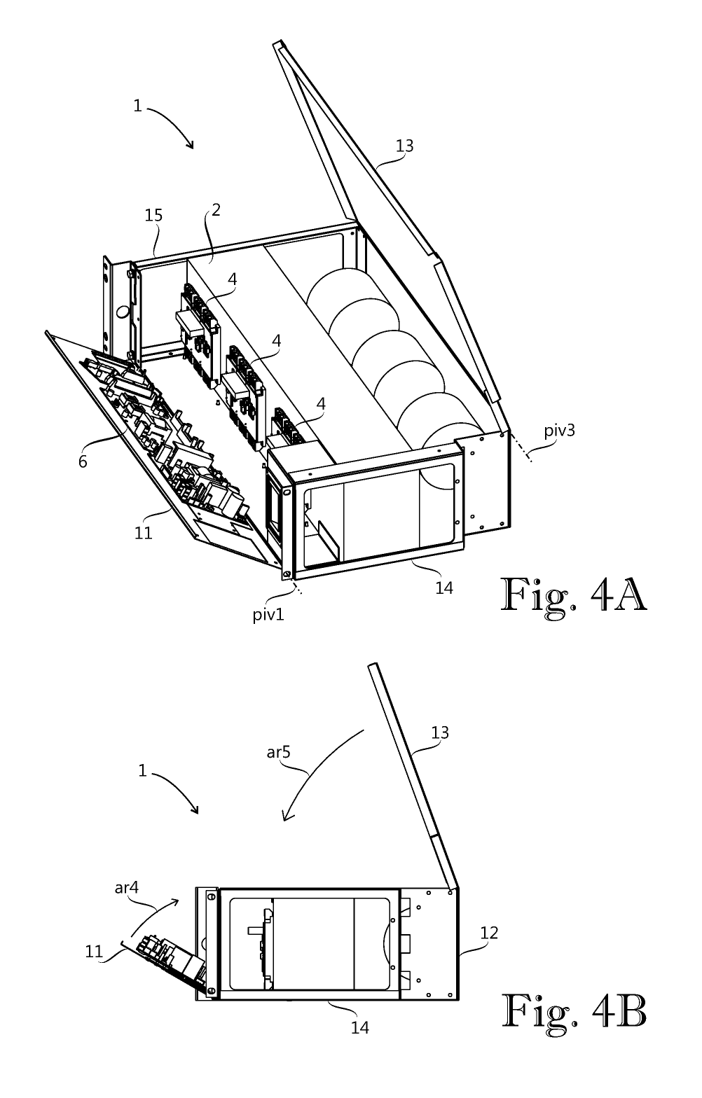

FIG. 4A illustrates assembling of the electrical device of FIG. 3A. In FIG. 4A the first wall 11 is between its first and second positions. The second wall 12 is in its first position relative to the frame 2. The third wall 13 is between its first and second positions. FIG. 4B shows the electrical device 1 of FIG. 4A from a direction perpendicular to the fourth wall plane. Arrows ar4 and ar5 illustrate directions in which the first wall 11 and the third wall 13 are turned during final assembly of the electrical device 1.

As defined above, FIG. 1 shows the electrical device 1 in the assembled state thereof. In the assembled state the first wall 11 and the second wall 12 are in their first positions relative to the frame 2, the third wall 13 is in the first position relative to the second wall 12, and the first wall plane and the second wall plane are substantially parallel to each other, and the third wall plane extends substantially perpendicular to the first wall plane and the second wall plane such that the first wall 11 forms a front wall of the electrical device, the second wall 12 forms a back wall of the electrical device, and the third wall 13 forms a side wall of the electrical device 1.

Although the door of the electric cabinet is not shown in FIG. 1, a pivoting axis of the door is denoted with reference sign piv4. When the door of the electric cabinet is in its closed position, a door plane defined by the door is parallel to the first wall plane defined by the first wall 11 in its first position. When the door of the electric cabinet is in its open position, the door plane is parallel to the first wall plane defined by the first wall 11 in its second position. When the door of the electric cabinet is in the open position and the first wall 11 is in the second position, the controller element 6 of the electrical device 1 is accessible for maintenance and repair.

It will be obvious to a person skilled in the art that the inventive concept can be implemented in various ways. The invention and its embodiments are not limited to the examples described above but may vary within the scope of the claims.

1. An electrical device comprising:
a frame;
a first wall connected to the frame;
a power converter adapted to convert electric energy from one form to another, the power converter comprising at least one power converter element; and
a controller adapted to control the power converter, the controller comprising at least one controller element,
wherein the first wall is pivotally connected to the frame about a first pivoting axis such that the first wall is adapted to pivot between a first position in which the first wall is adapted to protect the at least one controller element, and a second position which is adapted to provide an access to the at least one controller element for maintenance and repair.

2. The electrical device according to claim 1, wherein the second position of the first wall is further adapted to provide access to the at least one power converter element.

3. The electrical device according to claim 1, wherein the at least one controller element is attached to the first wall.

4. The electrical device according to claim 1 wherein the electrical device comprises a second wall pivotally connected to the frame about a second pivoting axis, such that the second wall is adapted to pivot about the second pivoting axis between a first position and a second position relative to the frame, the second pivoting axis being substantially parallel to the first pivoting axis.

5. The electrical device according to claim 4, wherein the electrical device comprises a third wall pivotally connected to the second wall about a third pivoting axis, the third wall is adapted to pivot about the third pivoting axis between a first position and a second position relative to the second wall, and the second pivoting axis is substantially parallel to the third pivoting axis.

6. The electrical device according to claim 5, wherein the first wall defines a first wall plane, the second wall defines a second wall plane, and the third wall defines a third wall plane, and the electrical device is adapted such that when the first wall and the second wall are in their second positions relative to the frame, and the third wall is in the second position relative to the second wall, the first wall plane, the second wall plane and the third wall plane are coplanar planes.

7. The electrical device according to claim 6, wherein the electrical device is adapted such that when the first wall and the second wall are in their first positions relative to the frame, and the third wall is in the first position relative to the second wall, the first wall plane and the second wall plane are substantially parallel to each other and the third wall plane extends substantially perpendicular to the first wall plane and the second wall plane such that the first wall forms a front wall of the electrical device, the second wall forms a back wall of the electrical device, and the third wall forms a side wall of the electrical device.

8. The electrical device according to claim 1, wherein the power converter comprises an inverter, a rectifier, a frequency converter or a DC-to-DC converter.

9. The electrical device according to claim 1, wherein the at least one power converter element comprises a plurality of controllable semiconductor switches.

10. An electrical device assembly comprising:
an electric cabinet defining a mounting space adapted to accommodate an electrical device, the electric cabinet comprising a openable door adapted to provide access into the mounting space in an open position of the door; and
an electrical device mounted in the electric cabinet, wherein the electrical device comprises:
a frame;
a first wall connected to the frame;
a power converter adapted to convert electric energy from one form to another, the power converter comprising at least one power converter element;
a controller adapted to control the power converter, the controller comprising at least one controller element;
wherein the first wall is pivotally connected to the frame about a first pivoting axis such that the first wall is adapted to pivot between a first position in which the first wall is adapted to protect the at least one controller element, and a second position which is adapted to provide an access to the at least one controller element for maintenance and repair; and
the electrical device assembly is adapted such that when the door of the electric cabinet is in the open position and the first wall is in the second position, the at least one controller element of the electrical device is accessible for maintenance and repair.

11. The electrical device assembly according to claim 10, wherein the second position of the first wall is further adapted to provide access to the at least one power converter element.

12. The electrical device according to claim 10, wherein the at least one controller element is attached to the first wall.

13. The electrical device according to claim 10, wherein the electrical device comprises a second wall pivotally connected to the frame about a second pivoting axis, such that the second wall is adapted to pivot about the second pivoting axis between a first position and a second position relative to the frame, the second pivoting axis being substantially parallel to the first pivoting axis.

14. The electrical device according to claim 13, wherein the electrical device comprises a third wall pivotally connected to the second wall about a third pivoting axis, the third wall is adapted to pivot about the third pivoting axis between a first position and a second position relative to the second wall, and the second pivoting axis is substantially parallel to the third pivoting axis.

15. The electrical device according to claim 14, wherein the first wall defines a first wall plane, the second wall defines a second wall plane, and the third wall defines a third wall plane, and the electrical device is adapted such that when the first wall and the second wall are in their second positions relative to the frame, and the third wall is in the second position relative to the second wall, the first wall plane, the second wall plane and the third wall plane are coplanar planes.

16. The electrical device according to claim 15, wherein the electrical device is adapted such that when the first wall and the second wall are in their first positions relative to the frame, and the third wall is in the first position relative to the second wall, the first wall plane and the second wall plane are substantially parallel to each other and the third wall plane extends substantially perpendicular to the first wall plane and the second wall plane such that the first wall forms a front wall of the electrical device, the second wall forms a back wall of the electrical device, and the third wall forms a side wall of the electrical device.

17. The electrical device according to claim 10, wherein the power converter comprises an inverter, a rectifier, a frequency converter or a DC-to-DC converter.

18. The electrical device according to claim 10, wherein the at least one power converter element comprises a plurality of controllable semiconductor switches.
